(19) United States
(12) Patent Application Publication
(10) Pub. No.: US 2012/0015523 A1
(43) Pub. Date: Jan. 19, 2012

(54) SYSTEMS AND METHODS FOR ETCHING SILICON NITRIDE

(76) Inventors: Jerry Dustin LEONHARD, Kalispell, MT (US); Eric Jeffery BERGMAN, Kalispell, MT (US)

(21) Appl. No.: 12/837,327

(22) Filed: Jul. 15, 2010

(51) Int. Cl. H01L 21/306

(52) U.S. Cl. 438/746; 257/E21.219

(57) ABSTRACT

To remove a silicon nitride layer on a silicon wafer, phosphoric acid is applied onto the wafer in a sealed chamber. The phosphoric acid may be atomized and sprayed onto the wafer as a mist or aerosol. The wafer is heated to a processing temperature and then maintained at or near the processing temperature with a coating of phosphoric acid on the wafer. The heating and applying phosphoric acid are then stopped, the wafer is cooled, and then removed from the process chamber. An infrared radiating assembly above the processing chamber may project infrared radiation into the chamber to heat the wafer. The wafer may be cooled by optionally spraying de-ionized water and/or nitrogen gas onto the workpiece. A cooling assembly may be used to cool an infrared radiating assembly. Silicon nitride is rapidly removed using very small amounts of phosphoric acid, and without the risks and disadvantages of conventional hot phosphoric bath techniques.

### BACKGROUND OF THE INVENTION

Silicon nitride (SiN) is commonly used in the semiconductor industry as an oxidation mask. Silicon dioxide (SiO2) will not grow underneath a SiN layer, because SiN has a very low oxygen permeability. The selective etch or removal of

SiN with a minimal removal of silicon dioxide is a desired result in many CMOS manufacturing processes. In the past, SiN etching has been performed using a heated bath of phosphoric acid and water. The heated bath is typically in the range of 165° C. Water is added to the bath to ensure a constant boiling mixture, which is believed necessary to maximize the SiN etch rate and process consistency. This heated bath process achieves SiN etch rates reportedly in the range from 20-100 angstroms per minute. However, in practice SiN etch rates only at the low end of this range are typically achieved, due to etch non-uniformity and the need to provide adequate over-etch to ensure complete removal of the SiN layer. Thus, the removal of a 1500 angstrom thick film of SiN will generally require 45 to 90 minutes. The selectivity of SiN removal to silicon dioxide removal using this process is generally in the range of 8:1, or around 2-3 angstroms per minute, so the loss of SiO2 can be significant during the SiN etch.

Due to these long processing times, the heated bath process is not well adapted for single-wafer processing. In addition, the need to pump and circulate the bath liquid at temperatures above 165° C. has various disadvantages. At this temperature, Teflon tubing becomes very soft, pumps and valves fail, and potential for leaks in the heated bath system increases. Manufacturing personnel must reliably avoid exposure to the bath liquid and vapors. This requires numerous safety features. Since the chemical solution is well above the boiling point of water, there is also a risk of a steam explosion which could spray the personnel with hot phosphoric acid and boiling water.

The etch rate and SiN:SiO2 selectivity of the hot phosphoric acid bath process are both also dramatically affected by the presence of dissolved silicon in the bath. In practice, this typically means that at least one batch of dummy wafers must be processed after fresh chemical is poured before the bath characteristics stabilize. Since the etch process may be in the range of 45 to 90 minutes, this bath conditioning is undesirable in terms of wafer usage and process throughput. In addition, the bath has a finite lifetime due to the loading effects of dissolved silicon and the evaporative losses of water. Complex management systems have been contrived to maintain the water content, but the bath will still degrade with usage due to the silicon loading. Bath life may be extended to a degree by partial exchange of the chemical, but at some point the bath must be fully exchanged, which leads once again to the issues regarding conditioning with a batch of dummy wafers, resulting in loss of time and use of wafers.

Accordingly, improved systems and methods for etching SiN are needed.

### SUMMARY OF THE INVENTION

New apparatus and methods for etching silicon nitride that overcome the problems with the heated bath techniques have now been invented. In a new method, a workpiece or wafer is placed into a process chamber. The process chamber is closed and sealed. Phosphoric acid is applied onto the workpiece. The phosphoric acid may be atomized and sprayed onto the workpiece as a mist or aerosol. The workpiece is quickly heated to a processing temperature and then maintained near the processing temperature. A film of phosphoric acid is maintained on the surface during processing. The heating is then stopped and the workpiece is quickly cooled. Infrared irradiation may be used to heat the workpiece. The workpiece may be cooled by optionally spraying de-ionized water and/or nitrogen gas onto the workpiece.

New apparatus for etching silicon nitride includes a processing chamber having a fixture for holding a workpiece. Atomizing nozzles in the processing chamber may be supplied with heated phosphoric acid. An infrared radiating assembly has infrared lamps outside of the processing chamber positioned to radiate infrared light into the processing chamber. A cooling assembly may be used to cool the infrared radiating assembly, and/or the process chamber. The new apparatus and methods allow for rapid etching of silicon nitride, using very small amounts of phosphoric acid, and without the risks and disadvantages of the heated bath methods.

### BRIEF DESCRIPTION OF THE DRAWINGS

In the drawings, the same reference number indicates the same element in each of the views.

FIG. 1 is a perspective view of a processor for carrying out a silicon nitride etch process.

FIG. 2 is a section view of the processor shown in FIG. 1.

FIG. 3 is a perspective section view of the processor shown in FIGS. 1 and 2.

FIG. 4 is a time v. temperature graph illustrating a silicon nitride etch process.

### DETAILED DESCRIPTION OF THE DRAWINGS

A new method for etching or removing silicon nitride from a silicon wafer uses phosphoric acid in a substantially enclosed or sealed chamber. Infrared energy may be radiated into the chamber to heat the wafer and phosphoric acid simultaneously. Heat may alternatively be provided via other types of radiation, such as microwave radiation. A heated wafer holder may also be used. This process allows for much higher temperatures to be safely used, while also minimizing phosphoric acid consumption by atomizing the bulk liquid phosphoric acid into an aerosol. The processor may have an upper chamber made of quartz to contain the liquid, aerosol, vapor and gas phase substances that may be used or created during processing, while allowing infrared radiation to pass through to irradiate the wafer. A wafer holder or rotor may also be made of quartz to hold the wafer while also reflecting IR radiation back onto the wafer. Silicon nitride etch rates greater than 2,000 angstroms per minute may be achieved. Due to a novel combination of high temperatures, infrared radiation, and shortened process times, the typical etch selectivity between silicon nitride and thermal (silicon) oxide can be increased from 10/1 to greater that 200/1.

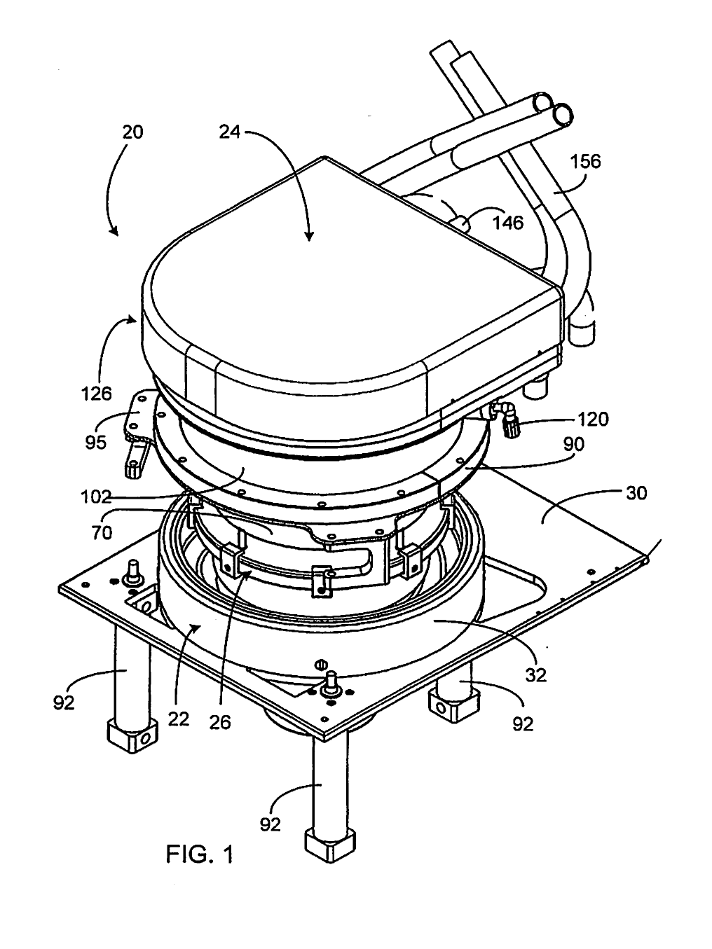

FIGS. 1-3 show a processor that may be used to perform the methods described. As shown in FIG. 1, a processor 20 may include a first or lower chamber assembly 22 and a second or upper chamber assembly 24. The lower chamber assembly 22 may include a bowl 32 supported on a base plate 30. A rotor assembly 26 adapted to hold and rotate a workpiece or wafer 70, such as a silicon wafer, is contained within the lower chamber assembly 22. Alternatively, a fixed or non-rotating wafer holder may be used. The wafer holder, or rotor if used, may include a heating element, to heat the wafer via conduction.

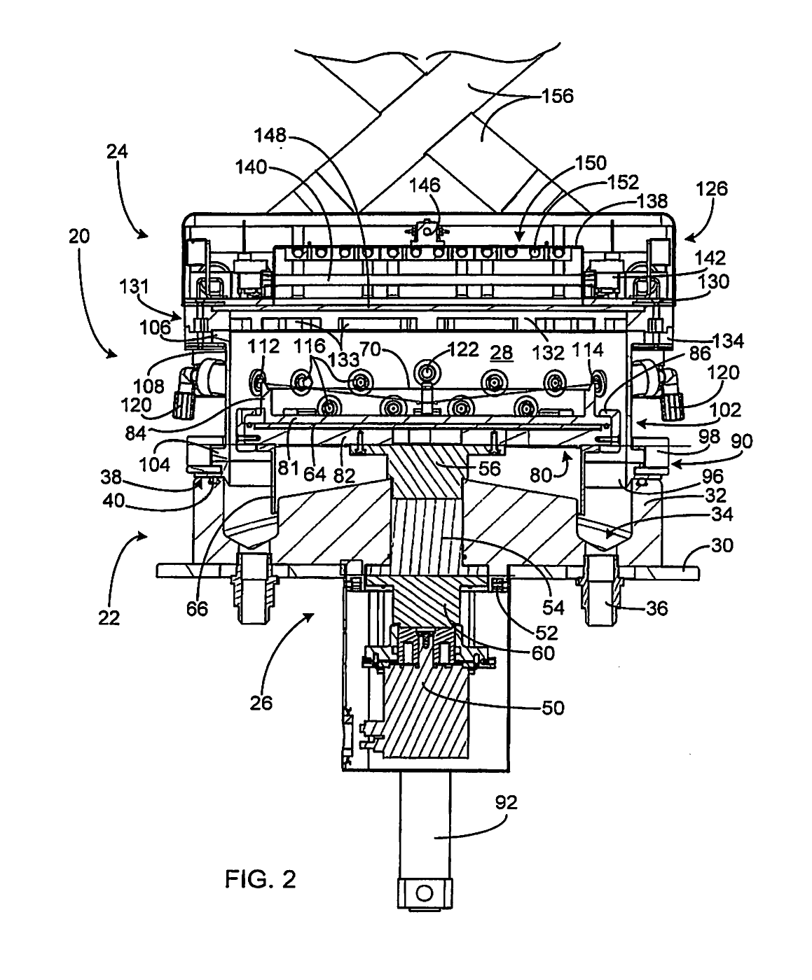

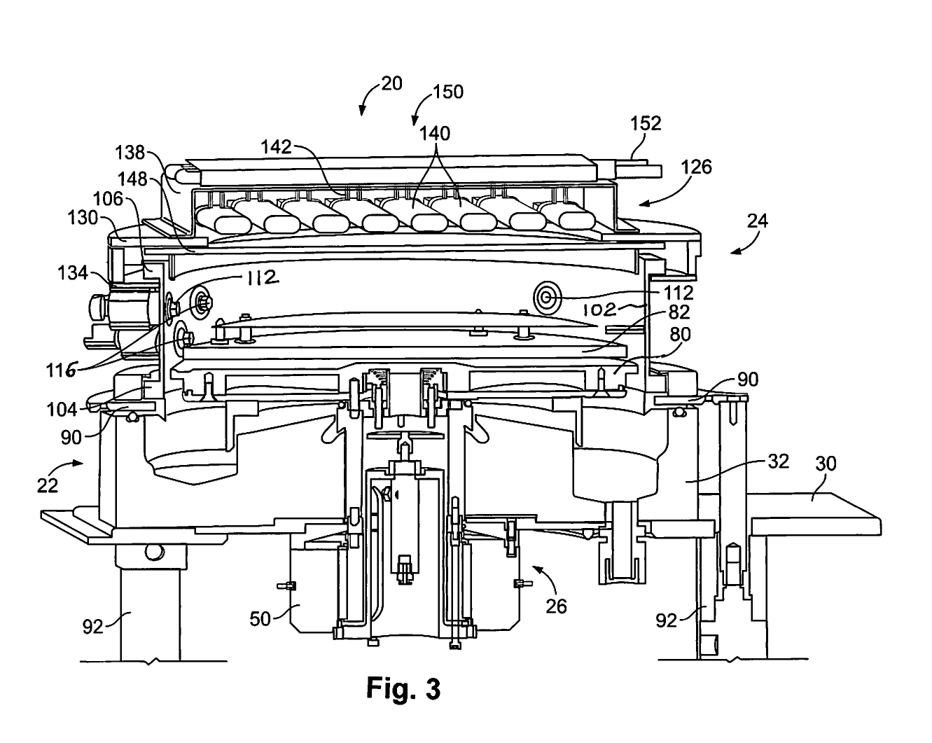

As shown in FIGS. 2-3, the bowl 32 may include a fluid collection trough 34 having a drain fitting 36, for collecting and removing fluid. A seal element 40, such as an o-ring, is provided on a top surface 38 of the bowl 32. The rotor assembly 26 includes a motor 50 that rotates a plate assembly 80 holding the wafer 70. Shield plate 64 is sandwiched in between top plate 81 and rotor plate 82, attached to rotor hub 56. Plate clip 86 holds the components of plate assembly 80 together. Fingers 84 extend perpendicularly from plate assembly 80, and are positioned around the periphery of rotor plate 82. Wafer 70 rests on fingers 84 spaced apart from, and substantially parallel to rotor plate 82. In the specific design shown in FIG. 2, the rotor assembly 26 also includes a rotor hub 56 connected to the upper and lower shaft, 54 and 60, respectively. The drive shaft rotates freely while the motor 50 remains fixed in place. The motor 50 may be supported on a motor mounting plate 52 attached to the base plate 30, to rotatably support the rotor assembly 26 in the lower chamber assembly 22.

Fingers 84 or similar devices on the rotor assembly are attached to the plate assembly 80 to support and hold the wafer 70 at the edges. A rotor curtain 66 is attached to the rotor assembly 26 to block liquid from reaching the upper drive shaft 54, lower drive shaft 60, and the motor 50. The rotor assembly 26 is representative of one of various designs that may be used.

Referring still to FIGS. 2-3, the upper chamber assembly 24 may include an annular upper chamber body 102 having a lower lip 104 and an upper lip 106. The body 102 can be attached to a lift ring 90 via a lower retainer ring 98. Referring momentarily to FIGS. 1, 2 and 3, lifting actuators 92 may be attached to ring tabs 95 on the lift ring 90. Lifting movement of the actuators accordingly lifts the entire upper chamber assembly 24 up and off of the lower chamber assembly 22. The lift ring 90 may therefore be made of corrosion resistant steel, or similar material. A bowl ring 96 may be provided over the lift ring 90, to shield the lift ring 90 from the corrosive acid used within the processor 20. As shown in FIG. 2, with the processor 20 in the closed or process position, the bottom surface of the bowl ring 96 engages the seal element 40, to seal the upper chamber assembly 24 to the lower chamber assembly 22.

In the design shown, the lifting actuators used include a lift actuator 92 supported on the base plate 30 and having a shaft extending up and attached to a ring tab 95. FIG. 1 shows use of three lift actuators, although more or less may be used.

In FIGS. 2 and 3, a processing chamber 28 is shown formed between the lower and upper chamber assemblies 22 and 24, when the processor 20 is in the closed or process position. Fluid outlets or nozzles provide process fluids into the chamber 28. Various nozzle numbers, types and positions may be used. The nozzles may be attached to the cylindrical sidewall 108 of the upper chamber body 102. Supply lines (not shown) deliver process fluids to the nozzles. Various types of nozzles may be employed, including atomizing and spray nozzles. To perform the processes described below, the processor 20 has phosphoric acid atomizing nozzles 112. The processor 20 may also include nitrogen gas nozzles, and upper and lower de-ionized water nozzles 116, for cooling the wafer. If used, the water nozzles 116 may be paired up in an upper and lower nozzle sets, relative to the wafer 70. Also as shown in FIG. 2, one or more chamber temperature sensors 122, such as a thermocouple or proxy sensor, may be provided in the chamber 28 to approximate the temperature of the wafer during processing.

Referring still to FIGS. 2 and 3, a head plate 130 is secured onto the upper chamber body 102 via an upper retainer plate 134. An exhaust plate 132 is held tight to the head plate 130, to secure an infrared transparent window 148 between them. The head plate 130 and the exhaust plate 132 each have a central through opening generally matching and generally centered on the plate assembly 80. The infrared transparent window 148 spans the opening and may be sealed to both the head plate 130 and the exhaust plate 132. The infrared transparent window 148 is positioned to permit light and/or IR energy to pass through the window and be absorbed by a wafer 70 positioned on the plate assembly 80. The exhaust plate 132 has at least one exhaust port 133. Exhaust ports 133 permit evacuation of the processing chamber 28.

A radiation or infrared (IR) assembly 126 may also be supported on the head plate 130 of the upper chamber assembly 24. As shown in FIG. 2, IR lamps 140 are provided in an array over the infrared transparent window 148. The lamps 140 may be suspended within a lamp housing 138 on holders or brackets 142. Electrical power cables 156 provide power to the lamps 140. Further description of the IR assembly and other aspects of the processor 20 are included in U.S. patent application Ser. No. 12/717,079, incorporated herein by reference..

A cooling system 150 is provided on the IR assembly 126. The cooling system may include tubes 152 on or in the lamp housing 138. Liquid coolant is pumped through the tubes 152, at appropriate times, to cool the IR assembly 126. The tubes 152 may extend through heat sink plates in the lamp housing 138. The cooling system 150 may also include an air manifold 146 and an air flow path through and/or around the lamp housing 138.

In use, the processor 20 is initially in the open or load/unload position shown in FIG. 1. The upper chamber assembly 24 is raised up from the lower chamber assembly 22, allowing access to the plate assembly 80 from the side. A wafer 70 is placed onto the top plate 81, manually, or more typically by a robot. The wafer rests on the fingers 84. The lift actuators 92 then lower the upper chamber assembly 24 down onto the lower chamber assembly 22, forming the processing chamber 28 between them. The processor 20 is then in the process position shown in FIGS. 2 and 3. The bowl ring 96 may seal against the seal 40 to substantially seal the chamber 28. The chamber 28 may be exhausted (via a vacuum line), and it need not necessarily be air tight. Rather, the processor 20 may alternatively be designed so that liquids, gases and vapors cannot readily escape into the surrounding environment.

Phosphoric acid is supplied into the chamber 28, preferably as an aerosol or atomized mist. The phosphoric acid can be generally supplied to the nozzles as a liquid, typically pre-heated to from about 50° C. to about 90° C. Pre-heating the liquid phosphoric acid, although not essential, may allow for faster processing. Pre-heating also reduces the viscosity of the liquid phosphoric acid, so that pumping it is easier. Fluid line components, such as Teflon piping, valves, pumps, and fittings can readily handle temperatures up to 90° C. Atomizing the phosphoric acid, rather than spraying, helps to avoid localized temporary cooling of the wafer. This improves processing uniformity across the wafer. In apparatus using a rotor, the motor 50 is activated to rotate the rotor assembly 26 and the wafer 70. Rotation speeds of 10-300 rpm may be used. Rotation helps to make the IR radiation and heating more uniform across the surface of the wafer 70. Atomizing the phosphoric acid minimizes chemical consumption. Typically, as little as 5 ml to 10 ml of phosphoric acid is sufficient to strip a 300 mm wafer.

Water may optionally be supplied onto the wafer either as an added constituent to the phosphoric acid, or separately applied as an aerosol from separate nozzles in the process chamber. Electronic grade phosphoric acid typically includes about 5% water. Additional water to provide some dilution of the phosphoric acid may be used.

Generally, while the wafer is being initially coated with phosphoric acid, the lamps 140 may be turned on and set at a reduced power level of e.g., 5% to 25% of maximum. The specific timing and sequence of the initial heating step may be varied, with the initial heating step performed before, after, or simultaneously with the initial application of phosphoric acid. The lamps 140 irradiate the wafer 70 through the window 148. The window 148 may be quartz, since quartz is substantially transparent to IR radiation, and it is also chemically inert and highly heat resistant. The upper chamber body 102 and the top plate 81 may also be quartz, to better resist high processing temperatures resulting from exposure to the IR radiation. The shield plate 64 within the plate assembly 80 helps to block the IR radiation from penetrating into the lower chamber assembly 22. The shield plate 64 may be quartz plate with a reflective coating. Components below the shield plate 64 generally may be conventional metal and plastic materials.

The temperature of the wafer 70 may be monitored by temperature sensor 122. The wafer temperature may be controlled in a closed feedback loop via temperature sensor 122 and adjusting power to the lamps 140. This may be performed by an electronic controller or computer associated with the processor 20, or remotely located in the facility. The controller may also control other operations of the processor. The temperature may be affected by the addition of phosphoric acid to the surface of the wafer during processing.

After the initial phase of coating the wafer with phosphoric acid, lamp power is increased to rapidly ramp up the wafer temperature to a processing temperature, typically between 200° C. and 250° C., although other ranges may also be used. Full lamp power (100% power) may be used for this step. The ramp up interval may last from about 20 to 80 seconds, depending on the equipment design, the desired processing temperature, and potentially other factors as well, such as the specific chemical make up of the SiN layer and the phosphoric acid.

The wafer temperature is then held at or near the desired processing temperature for a dwell interval, typically ranging from 20-100, 30-80, or 40-70 seconds. Lamp power is adjusted to maintain the wafer temperature at or near the desired processing temperature. Typically, lamp power is set at about 30% to 60% during this interval. Additional phosphoric acid may be added to the wafer surface to maintain the film. The phosphoric acid may be added by various devices, including by an atomizer, or spray nozzle, in the form of an aerosol. Additionally, the phosphoric acid may be applied in various ways, including continuously, pulsed, metered, regulated, and optionally as determined by a sensor and/or specified parameters.

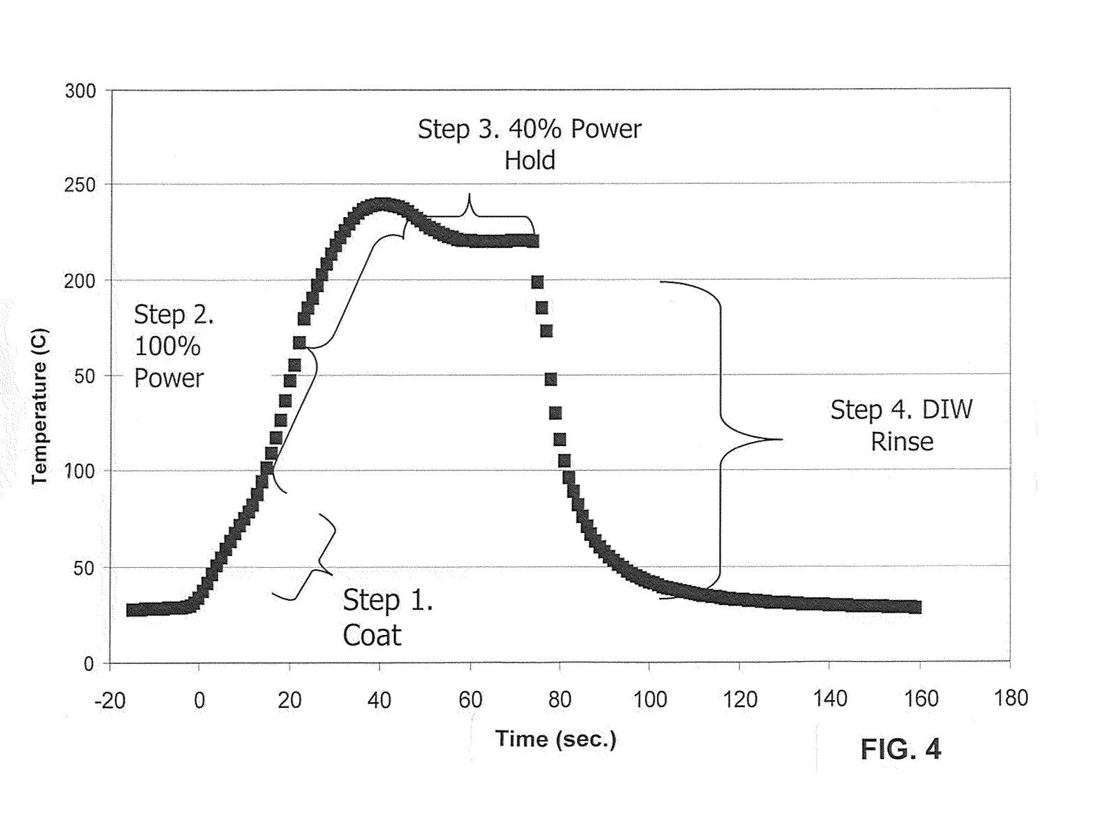

The wafer 70 may then be rapidly cooled, to shorten processing time. Rapid cooling can be achieved via the cooling assembly 150, which primarily cools the IR lamps 140 and lamp housing 138. A fluid spray of nitrogen gas and/or de-ionized water onto the wafer 70 may be used to cool the wafer 70. Some silicon nitride layers may be completely removed during the ramp up interval, making the dwell interval unnecessary. FIG. 4 shows a time/temperature graph of one example of the process described above. In the example in FIG. 4, the ramp up time is 20 seconds, the dwell time is 40 second, and the cooling time is 20 seconds.

In the cooling assembly 150, cooling water may be pumped through the tubes 152 when the lamp housing 138 exceeds a preset temperature, as detected by the lamp housing temperature sensors 144. Generally, cooling water moves through the tubes or coils 152 whenever the lamps 140 are on, and for a period of time after they are turned off. Clean dry air may be pumped or drawn through IR assembly 126 to provide additional cooling. The cooling assembly 150 blocks stray IR radiation from the IR assembly 126 and reduces or avoids heating up adjacent apparatus.

When processing is completed, the lift actuators 92 lift the upper chamber assembly 24 back up off of the lower chamber assembly 22. The processed wafer 70 may then be removed and a subsequent wafer loaded into the processor 20. The processed wafer 70 may be moved into a cleaning chamber which performs a cleaning step, such as an ammonia peroxide cleaning step, followed by a drying step.

In contrast to the conventional hot phosphoric acid bath approach, the processor 20 allows for processing at very high temperatures. Boiling does not limit processing temperatures because the phosphoric acid is not provided in bulk liquid form into the process chamber. Similarly, pumping and handling of high temperature phosphoric acid is not required, which simplifies the system design, and improves reliability. The high processing temperatures reduces the required processing time from typically 30-90 minutes using conventional methods, to about 30 to 90 seconds using the present methods. The heated phosphoric acid bath and the relatively complicated apparatus and safety systems required to operate it are no longer needed.

There are a number of advantages to this process, including that the risks of “flash evaporation” during water injection into the bath system are avoided. Additionally, the elevated temperature eliminates the need for the presence of water in order to achieve the optimal etch rate of SiN and selectivity to SiO2. Further, it eliminates the need for conditioning the chemical bath by running dummy wafers to provide a certain level of dissolved silicon loading into the bath. This avoids the costly delay in processing and the use of dummy wafers to condition the bath.

Since only a few milliliters of phosphoric acid are used in processing each wafer, material costs are very low. The low consumption of phosphoric acid makes recycling and reusing the used phosphoric acid unnecessary. As a result, each wafer is processed using fresh phosphoric acid. The complexities of acid reuse and the risks of contamination caused by reuse are avoided. The apparatus and methods described make it possible to perform SiN strip using single-wafer processing technology. Since modern semiconductor device manufacturing is increasingly moving towards single-wafer processing, the present apparatus and methods are increasingly well adapted for use in the semiconductor device manufacturing industry.

A processor for etching silicon nitride on a wafer may comprise: a sealable processing chamber; a fixture in the processing chamber for holding a wafer; a plurality of atomizing nozzles in the processing chamber; a source of phosphoric acid connected to the nozzles; a heater for heating the phosphoric acid; an infrared radiating assembly including a plurality of infrared lamps outside of the processing chamber and positioned to radiate infrared light into the processing chamber; and a cooling assembly associated with the infrared radiating assembly. The fixture may be a rotor. The processing chamber may have nozzles for spraying de-ionized water and/or nitrogen gas onto the wafer, to cool the wafer. The infrared radiating assembly may be adapted to heat the wafer from room temperature to over 200° C. in less than 60 seconds.

Depending on process parameters, silicon nitride etch rates may exceed 2,000 angstroms per minute, and etch selectivity between the silicon nitride and silicon oxide of greater that 200/1 may be achieved. If the phosphoric acid preheating step is used, the phosphoric acid may be supplied into the process chamber at a temperature of 50° to 90° C. In certain embodiments, less than 40 ml, 20 ml, 10 ml or 5 ml, of phosphoric acid may be used on each wafer. Heating times and temperatures may be varied, with one embodiment including heating the wafer to a temperature of at least 200° C. within 60 seconds. A dwell time of 50 seconds or less may be used.

Thus, novel methods and apparatus have been shown and described. Various changes and substitutions may of course be made without departing from the spirit and scope of the invention. The invention, therefore, should not be limited, except to the following claims and their equivalents.

1. A method for etching silicon nitride on a workpiece, comprising:
a) placing the workpiece into a process chamber;
c) applying phosphoric acid onto the workpiece;
d) heating the workpiece to a process temperature;
e) maintaining the workpiece within a range of the process temperature;
f) cooling the workpiece; and
g) removing the workpiece from the process chamber.

2. The method of claim 1 wherein the heating is performed by irradiating the workpiece with infrared light.

3. The method of claim 2 further including irradiating the workpiece with infrared light at an initial higher intensity until the workpiece reaches the process temperature, and then irradiating the workpiece at a subsequent lower intensity, to maintain the workpiece at the process temperature.

4. The method of claim 3 further 3 wherein phosphoric acid is continuously applied onto the workpiece while the workpiece is maintained at the process temperature.

5. The method of claim 2 wherein the workpiece is cooled by stopping the irradiation of the workpiece with infrared light.

6. The method of claim 5 further comprising cooling the workpiece by applying de-ionized water onto the workpiece.

7. The method of claim 2 further comprising cooling the workpiece by spraying nitrogen onto the workpiece.

8. The method of claim 1 further comprising placing the workpiece into a cleaning chamber and cleaning the workpiece in the cleaning chamber, after removing the workpiece from the process chamber.

9. The method of claim 8 wherein the workpiece is cleaned in the cleaning chamber by applying an ammonium peroxide mixture onto the workpiece, and then rinsing and drying the workpiece.

10. The method of claim 1 wherein the workpiece has a device side and a back side, and wherein the workpiece is placed into the process chamber with the device side up.

11. The method of claim 1 wherein steps c) through f) are performed in less than 100 seconds.

12. The method of claim 1 further including rotating the workpiece within the process chamber.

13. The method of claim 1 with the phosphoric acid applied in as a mist.

14. The method of claim 1 with steps c) and d) performed simultaneously.

15. A method for etching silicon nitride on a wafer, comprising:
applying a mist of phosphoric acid onto the wafer within a process chamber;
raising the temperature of the wafer to a process temperature over 200° C. in less than 60 seconds;
maintaining the wafer at the process temperature for less than 80 seconds while applying phosphoric acid onto the wafer;
cooling the wafer; and
removing the wafer from the process chamber.

16. The method of claim 15 wherein the heating is performed by irradiating the wafer with infrared light.

17. The method of claim 15 further comprising cooling the wafer by applying de-ionized water onto the wafer.

18. The method of claim 15 wherein the silicon nitride on the wafer is etched in step e) at a rate greater than 2,000 angstroms per minute.

19. The method of claim 15 further including rotating the wafer within the process chamber.

20. A method for removing silicon nitride from a surface of a silicon wafer, comprising:
placing the wafer into a process chamber;
sealing the process chamber;
rotating the wafer;
applying an aerosol of phosphoric acid onto the wafer within a sealed process chamber;
raising the temperature of the wafer to a process temperature between 200° C. and 280° C. in less than 60 seconds by irradiating the wafer with infrared light;
maintaining the wafer at the process temperature for less than 60 seconds while substantially continuously applying phosphoric acid onto the wafer;
stopping the irradiating of the wafer and stopping the applying of an aerosol of phosphoric acid onto the wafer;
cooling the wafer by applying de-ionized water onto the wafer;
unsealing and opening the process chamber; and
removing the wafer from the process chamber.
